(19) United States
(12) Patent Application Publication
(10) Pub. No.: US 2025/0293012 A1
(43) Pub. Date: Sep. 18, 2025

(54) SYSTEM AND METHOD FOR SEMICONDUCTOR PROCESSING

(71) Applicant: Tokyo Electron Limited, Tokyo (JP)

(72) Inventors: Qi Wang, Albany, NY (US); Nicholas Smieszek, Albany, NY (US); Sergey Voronin, Albany, NY (US); Akiteru Ko, Albany, NY (US); Blaze Messer, Albany, NY (US); Joel Ng, Fremont, CA (US); Da Song, Albany, NY (US); Ashawaraya Shalini, Fremont, CA (US)

(21) Appl. No.: 18/602,850

(22) Filed: Mar. 12, 2024

(51) Int. Cl. H01J 37/32

(52) U.S. Cl. CPC H01J 37/32981; H01J 37/32449; H01J 37/32834; H01J 37/32963; H01J 2237/3341

(57) ABSTRACT

A system for gas measurement includes an exhaust line coupled with a semiconductor processing chamber, an exhaust plasma chamber coupled with the exhaust line, an optical emission spectroscopy (OES) detector coupled to the exhaust plasma chamber, and a flow controller device coupled to the exhaust plasma chamber and the exhaust line by a gas injection line. The exhaust plasma chamber is configured to generate a plasma from gas received through the exhaust line. The flow controller device is configured to inject gas into the exhaust plasma chamber.

### TECHNICAL FIELD

The present invention relates generally to semiconductor processing, and, in particular embodiments, to a system and method for gas phase measurement and plasma based endpoint detection.

### BACKGROUND

Device formation within microelectronic workpieces can involve a series of manufacturing techniques including formation, patterning, and removal of a number of layers of material on a substrate. In order to achieve the physical and electrical specifications of current and next generation semiconductor devices, processing flows enabling reduction of feature size while maintaining structural integrity is desirable for various patterning processes. As device structures densify and develop vertically, the desire for precision material processing becomes more compelling.

Plasma processes are commonly used to form devices, interconnects, and contacts in microelectronic workpieces. For example, plasma etching and plasma deposition are common process steps during semiconductor device fabrication. A combination of source power (SP) applied to a coupling element and bias power (BP) applied to a substrate holder can be used to generate and direct charged species from plasma. Various conditions during a plasma process may influence interactions of plasma ions with substrates and resulting effectiveness of etching. As such, improved measurement of plasma processes is desirable.

### SUMMARY

In accordance with an embodiment, a system for gas measurement includes: an exhaust line coupled with a semiconductor processing chamber; an exhaust plasma chamber coupled with the exhaust line, the exhaust plasma chamber configured to generate a plasma from gas received through the exhaust line; an optical emission spectroscopy (OES) detector coupled to the exhaust plasma chamber; and a flow controller device coupled to the exhaust plasma chamber and the exhaust line by a gas injection line, the flow controller device configured to inject gas into the exhaust plasma chamber.

In accordance with another embodiment, a system for semiconductor processing includes: a semiconductor processing chamber; a turbomolecular pump coupled to the semiconductor processing chamber, the turbomolecular pump configured to remove exhaust gas from the semiconductor processing chamber; an exhaust plasma chamber coupled with the turbomolecular pump, the exhaust plasma chamber including a viewport, the exhaust plasma chamber configured to generate a plasma from the exhaust; an optical emission spectroscopy (OES) detector coupled to the viewport by a fiber optic cable; a flow controller device coupled with the exhaust plasma chamber by a gas injection line, the flow controller device configured to inject gas into the exhaust plasma chamber; a pressure gauge coupled with the exhaust plasma chamber; and a controller coupled with the OES detector, the flow controller device, and the pressure gauge, the controller being configured to: receive pressure feedback data from the pressure gauge; receive data from the OES detector; and control a pressure in the exhaust plasma chamber by sending control signals to the flow controller device.

In accordance with yet another embodiment, a method for semiconductor processing includes: performing a semiconductor process in a semiconductor processing chamber; pumping an exhaust from the semiconductor process into an exhaust plasma chamber coupled with the semiconductor processing chamber; generating a plasma in the exhaust plasma chamber from the exhaust; based on pressure readings from a pressure gauge coupled with the exhaust plasma chamber, adjusting a pressure inside the exhaust plasma chamber by injecting a gas; and performing an optical emission spectroscopy measurement on the plasma.

It is to be understood that both the foregoing general description and the following detailed description are exemplary and explanatory only and are not restrictive of the disclosure, as claimed.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a semiconductor processing system, in accordance with some embodiments;

FIG. 2 illustrates an example optical emission spectroscopy (OES) graph;

FIG. 3 illustrates an OES spectrum graph, in accordance with some embodiments;

FIG. 4A illustrates a cross-sectional view of a semiconductor structure during an intermediate stage of manufacturing, in accordance with some embodiments;

FIG. 4B illustrates a cross-sectional view of a semiconductor structure during an intermediate stage of manufacturing, in accordance with some embodiments;

FIG. 4C illustrates a cross-sectional view of a semiconductor structure during an intermediate stage of manufacturing, in accordance with some embodiments;

FIG. 4D illustrates a cross-sectional view of a semiconductor structure during an intermediate stage of manufacturing, in accordance with some embodiments; and

FIG. 5 illustrates a process flow chart diagram of a method for semiconductor processing, in accordance with some embodiments.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

According to one or more embodiments of the present disclosure, this application relates to systems and methods for plasma measurement, such as improved optical emission spectroscopy (OES) systems. Conventional OES systems may have limited sensitivity to weakly ionized gases or plasma-less processes. Additional plasma excitation units, such as exhaust-based plasma units, may be useful for addressing this limited sensitivity. Although exhaust plasma excitation units may have wide operating windows, some operating regimes (e.g., low pressure regimes such as less than 10 mT or the like) may be a limiting factor for metrology techniques. Embodiments of the present disclosure may improve operating windows and operating stability of external OES plasma excitation units, thereby enabling additional metrology capabilities.

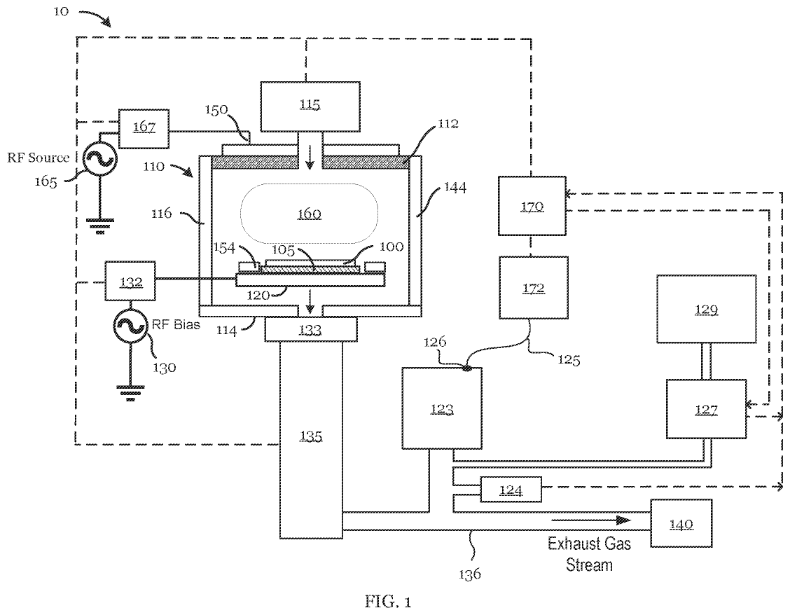

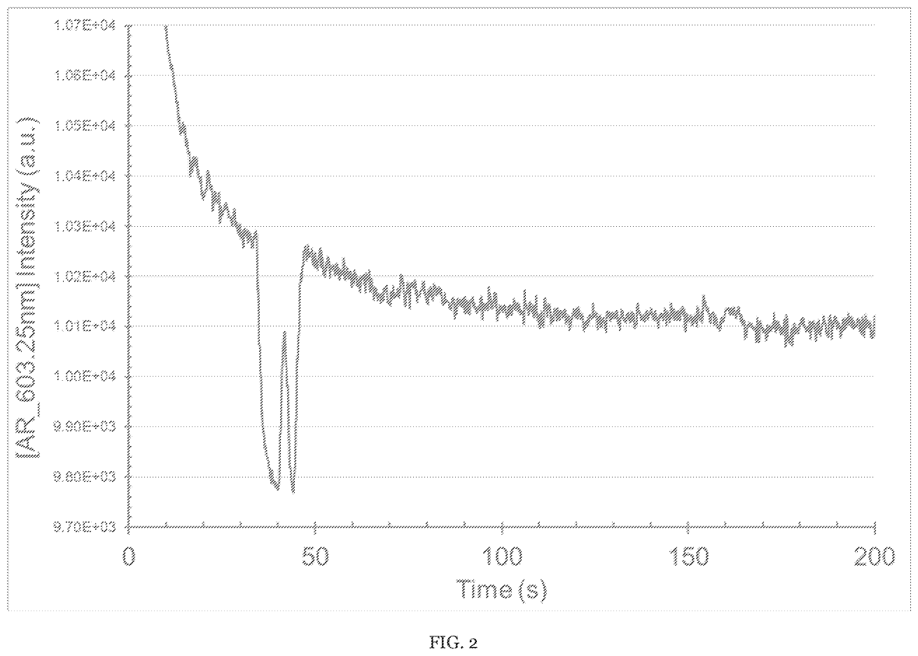

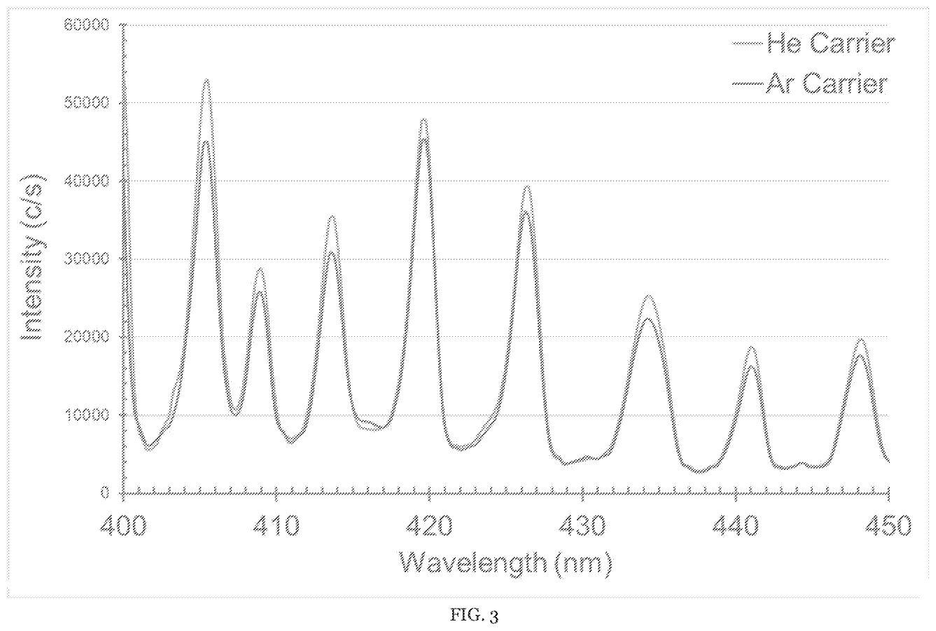

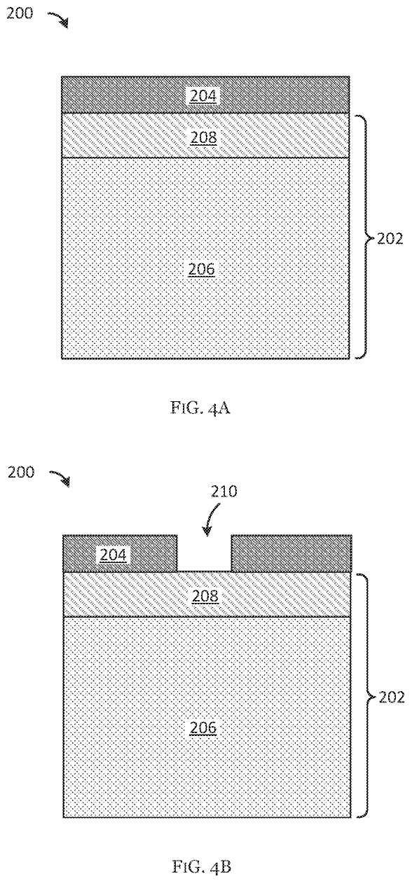

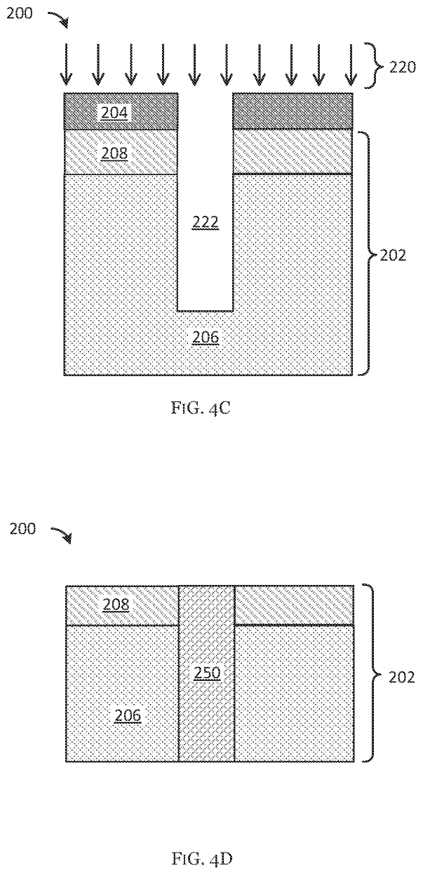

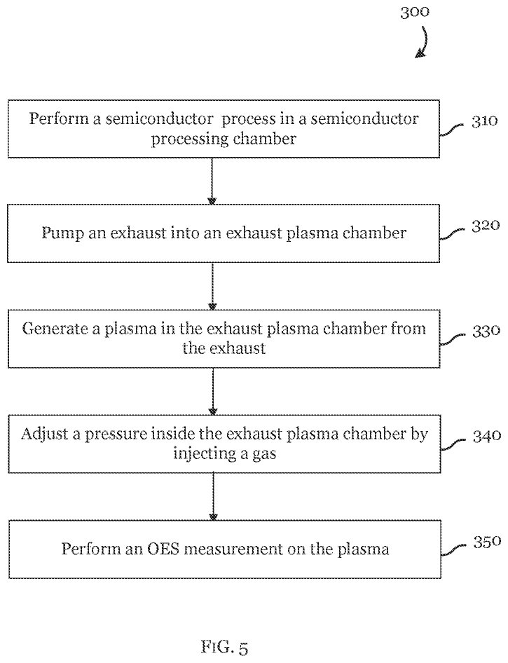

Embodiments of the disclosure are described in the context of the accompanying drawings. Embodiments of semiconductor processing systems will be described using FIG. 1. Embodiments of optical emission spectroscopy (OES) metrology will be described using FIGS. 2 and 3. An embodiment of a method for processing a substrate will be described using FIGS. 4A-4D. An embodiment of a method for semiconductor processing will be described using FIG. 5.

FIG. 1 illustrates an example semiconductor processing system 10 including an improved optical emission spectroscopy (OES) system, in accordance with some embodiments. As illustrated in FIG. 1, the semiconductor processing system 10 comprises a processing chamber 110. In the example illustrated by FIG. 1, the processing chamber 110 is a plasma processing chamber with source power excitation and substrate bias power (in other words, wafer biasing capabilities). However, embodiments of the disclosure may also be used with remote plasma systems, plasma-less processing systems, systems employing weakly ionized gases, the like, or a combination thereof.

As illustrated by FIG. 1, the processing chamber 110 comprises a top plate 112, a bottom plate 114, and a side wall 116. The top plate 112, bottom plate 114, and side wall 116 may be conductive and electrically connected to the system ground (a reference potential). Further in FIG. 1, a conductive coupler 150 used for inductively coupled plasma (ICP) is located outside the processing chamber 110, positioned above a top plate 112. The conductive coupler 150 can be a capacitively-coupled plasma processing apparatus, inductively-coupled plasma processing apparatus, microwave plasma processing apparatus, Radial Line Slot Antenna (RLSATM) microwave plasma processing apparatus, electron cyclotron resonance (ECR) plasma processing apparatus, remote plasma, or other types of processing systems or combination of systems. In various examples, the conductive coupler 150 is a conductive helical coil electrode used to inductively ignite and couple power to a plasma 160 inside the processing chamber 110. In other examples, the conductive coupler 150 is a conductive plate used to capacitively ignite and couple power to a plasma 160 inside the processing chamber 110. However, any suitable conductive coupler 150 may be used. The conductive coupler 150 may be coupled to a radio frequency (RF) source 165 via a matching circuit 167.

The matching circuit 167 typically includes one or more capacitors and inductors. In examples, the capacitors and inductors may be variable. The forward and reflected power at the matching circuit 167 can be measured, and the matching circuit 167 is used to match the plasma impedance. For example, a feedback loop circuit may be used to adjust the variable capacitors and inductors.

A substrate 100 may be placed on a substrate holder 105 in the processing chamber 110. In some examples, the substrate 100 is a semiconductor wafer used for manufacturing various semiconductor devices such as integrated circuits. However, the substrate 100 may be any suitable substrate to be exposed to a plasma or plasma-less process.

In various examples, the semiconductor processing system 10 may further comprise a focus ring 154 positioned over a bottom electrode 120 to surround the substrate 100. The focus ring 154 may advantageously maintain and extend the uniformity of a plasma 160 to achieve process consistency at the edge of the substrate 100. In various examples, the focus ring 154 may have a width of a few centimeters. In various examples, there may be a gap for mechanical clearance between the circumference of the substrate 100 and the focus ring 154. In certain examples, the gap may be hundreds of microns to a few millimeters. In various examples, the focus ring 154 comprises a dielectric material with a desired dielectric constant. In certain examples, the focus ring 154 comprises silicon. Some examples of silicon-based focus ring comprise silicon, silicon oxide, doped silicon (e.g., boron-doped, nitrogen-doped, and phosphorous-doped), or silicon carbide. Alternatively, in some examples, the focus ring comprises a carbon-based material. In one or more examples, the focus ring 154 may comprise a metal oxide, such as aluminum oxide and zirconium oxide.

A process gas is introduced into the processing chamber 110 by a gas delivery system 115. The gas delivery system 115 may comprise multiple gas flow controllers to control the flow of multiple gases into the processing chamber 110. Any reactive precursors or precursors that can create a plasma may be used, such as argon (Ar), tetrafluoromethane (CF₄), oxygen (O₂), an admixture of tetrafluoromethane and oxygen (CF₄/O₂), chlorine (Cl₂), fluoromethane (CH₃F), trifluoromethane (CHF₃), difluoromethane (CH₂F₂), hexafluorobutadiene (C₄F₆), octafluorocyclobutane (C₄F₈), nitrogen (N₂), hydrogen (H₂), hydrogen bromide (HBr), the like, or any combination, or admixture thereof in any suitable ratio. In some examples, optional center/edge splitters may be used to independently adjust the gas flow rates at the center and edge of the substrate 100.

The gas delivery system 115 may have a showerhead configuration positioned at the top of the processing chamber 110 covering the entirety of the substrate 100, including a plurality of appropriately spaced gas inlets. Alternatively, gas may be introduced through dedicated gas inlets of any other suitable configuration. The processing chamber 110 may further be equipped with one or more sensors such as voltage-current sensors, pressure monitors, gas flow monitors, and/or gas species density monitors. The sensors may be integrated as a part of the gas delivery system 115 in various examples.

In FIG. 1, the processing chamber 110 is a vacuum chamber and may be evacuated using one or more vacuum pumps, such as a single stage pumping system or a multistage pumping system. In order to promote even gas flow during semiconductor processing, gas may be removed from more than one gas outlet or location in the processing chamber 110 (e.g., on opposite sides of the substrate 100). In some embodiments, a turbomolecular pump (TMP) 135 evacuates the processing chamber 110. The turbomolecular pump (TMP) 135 is coupled through an exhaust line 136 with a dry pump 140 that is used to direct an exhaust gas stream out of the turbomolecular pump 135. As illustrated, the semiconductor processing system 10 may include an automatic pressure control (APC) valve 133 located between the processing chamber 110 and the turbomolecular pump 135. The automatic pressure control valve 133 may be adjusted to reduce gas conductance and increase pressure in the processing chamber 110.

In various examples, the substrate holder 105 may be integrated with, or a part of, a chuck (e.g., a circular electrostatic chuck (ESC)) positioned near the bottom of the processing chamber 110, and connected to a bottom electrode 120. The surface of the chuck or the substrate holder 105 may be coated with a conductive material (e.g., a carbon-based or metal-nitride based coating). The substrate 100 may be optionally maintained at a desired temperature using a temperature sensor and a heating element connected to a temperature controller (not shown). In certain examples, the temperature sensor may comprise a thermocouple, a resistance temperature detector (RTD), a thermistor, or a semiconductor based integrated circuit. The heating element may for example comprise a resistive heater in one example. In addition, there may be a cooling element such as a liquid cooling system coupled to the temperature controller.

The bottom electrode 120 may be coupled to a RF bias source 130, such as through a matching circuit 132. The matching circuit 132 may comprise similar components in similar configurations as described above for the matching circuit 167, and the details are not repeated herein. In some examples, the RF bias source 130 provides a sinusoidal waveform to the bottom electrode 120.

The semiconductor processing system 10 comprises an optical emission spectroscopy (OES) system based on an exhaust plasma chamber 123 (also referred to as an exhaust plasma unit, exhaust plasma excitation unit, or exhaust plasma excitation coupler) that is coupled to one or more additional gas(es) through a gas injection line coupled with flow controller(s) 127 (also referred to as a flow controller device). This may be advantageous by improving the operating windows and operating stability of the exhaust plasma chamber 123 and thereby enabling additional metrology capabilities.

The exhaust plasma chamber 123 is coupled to the exhaust line 136 between the turbomolecular pump 135 and the dry pump 140. The exhaust plasma chamber 123 is configured to receive the exhaust gas (e.g. at least 10%, such as 20%, 50%, 70%, 75%, 80%, 85%, 90%, 95%, 100%, and any values therebetween) from the processing chamber 110 through the turbomolecular pump 135. In various embodiments, the exhaust plasma chamber 123 includes a plasma coupling system (not illustrated) configured to generate a plasma from the received exhaust gas (also referred to as an exhaust). For example, the plasma coupling system may comprise a radio frequency (RF) source coupled through a matching circuit to a conductive coupler. The RF source, matching circuit, and conductive coupler may be similar to the RF source 165, matching circuit 167, and conductive coupler 150, but may have smaller sizes due to the smaller volume of the exhaust plasma chamber 123 in comparison with the processing chamber 110. The exhaust plasma chamber 123 further comprises a viewport 126, which may be a suitable transparent material or aperture to permit a fiber optic cable to receive light from the interior of the exhaust plasma chamber 123. An optical emission spectroscopy (OES) detector 172 is coupled to the viewport 126 by a fiber optic cable 125.

A gas supply 129 is further coupled between the exhaust plasma chamber 123 and the exhaust line 136 through a flow controller 127. The gas supply 129 provides one or more additional gas(es) such as, for example, a carrier gas such as argon (Ar), helium (He), xenon (Xe), or the like, a reactive gas such as nitrogen (N₂), oxygen (O₂), or the like, or a combination thereof, to the flow controller 127 for injection into the exhaust plasma chamber 123. In some embodiments, the flow controller 127 comprises one or more flow meter(s), such as a respective flow meter for each different gas of the gas supply 129. This separate gas inlet (or inlets) to the exhaust plasma chamber 123 provides a controllable flow rate and pressure of gas into the exhaust plasma chamber 123. This may be advantageous by providing stability to the plasma coupling in the exhaust plasma chamber 123 through adjusting pressure and plasma chemistry. For example, easily ionized gases may be injected into the exhaust plasma chamber 123. This may expand the operating window for the exhaust plasma chamber 123 and the metrology techniques of the OES detector 172 coupled with it. Different photon wavenumbers and intensity may have a direct relationship with plasma temperature. The plasma temperature may be controlled to achieve metrology expansion by controlling the pressure and chemistry in the exhaust plasma chamber 123, such as by controlling the pressure and species of gas injected into the exhaust plasma chamber 123 with the flow controller 127. Additional OES data may be provided by selection of additional gas composition and exhaust pressure, which may allow for retrieving different OES spectra for one semiconductor process recipe. These changes in pressure and composition of the exhaust gas do not have any effect on processes being performed in the processing chamber 110, since the exhaust gas is separated from the processing chamber 110 by a pumping system (e.g., the turbomolecular pump 135 and the automatic pressure control valve 133.

In some embodiments, a pressure gauge 124 is coupled between the exhaust line 136 and the exhaust plasma chamber 123. The pressure gauge 124 may be used to measure the pressure of gas flowing into the exhaust plasma chamber 123 and thereby provide feedback to the flow controller 127 in order to control the pressure inside of the exhaust plasma chamber 123. This may enable more stable operation of the exhaust plasma chamber 123 and widen the operating window for the exhaust plasma chamber 123 as used for optical emission spectroscopy (OES) measurements and/or endpoint detection (EPD).

The semiconductor processing system 10 further comprises a controller 170 to control plasma and/or gas processing and adjust parameters in real time. In some examples, the controller 170 comprises a programmable processor, microprocessor, computer, microcontroller, central processing unit (CPU), programmable logic devices (e.g. complex programmable logic device (CPLD)), field programmable gate array (FPGA), the like, or a combination thereof. Although the controller 170 is illustrated as a single element for illustrative purposes, the controller 170 may include additional elements or be part of a single element. The controller 170 may be programmable by instructions stored in software, firmware, hardware, one or more non-transitory computer-readable mediums (e.g. memory storage devices, FLASH memory, DRAM memory, reprogrammable storage devices, hard drives, floppy disks, DVDs, CD-ROMs, or the like), or a combination thereof.

The controller 170 may be coupled to the RF source 165, the matching circuit 167, the RF bias source 130, the matching circuit 132, the gas delivery system 115, the turbomolecular pump 135, the optical emission spectroscopy (OES) detector 172, the flow controller 127, and the pressure gauge 124. The controller 170 may be configured to set, monitor, and/or control various control parameters associated with generating a plasma and delivering ions to the surface of a microelectronic workpiece (e.g., the substrate 100). Control parameters may include, but are not limited to, power level, frequency, and duty cycle (%) for the source power, the bias power, and the DC voltage. Other control parameter sets may also be used. While only one RF source 165 is illustrated in FIG. 1, more than one RF source(s) 165 may be used in various examples, for example, to provide a low frequency RF power and a high frequency RF power at the same time. While only one RF bias source 130 is illustrated in FIG. 1, more than one RF bias source(s) may be used in various examples, for example, to provide a low frequency bias RF power and a high frequency bias RF power at the same time and enable changing the bias RF frequency more rapidly.

The controller 170 is further configured to receive data from the OES detector 172 and pressure feedback data from the pressure gauge 124 and to send instructions (such as control signals) to the flow controller 127 in order to control the pressure and composition of gas inside the exhaust plasma chamber 123. The controller 170 may introduce additional gases from the gas supply 129 through the flow controller 127 into the exhaust plasma chamber 123 for advanced OES analysis and operating stability. The pressure gauge 124 and one or more gas flow meter(s) of the flow controller 127 provide automatic feedback to the controller 170 in order to control the flow of gas into the exhaust plasma chamber 123.

For example, if the flow rate for a semiconductor process being performed inside the processing chamber 110 is low, the pressure of the exhaust reaching the exhaust plasma chamber 123 may be below the operating window of the exhaust plasma chamber 123 and the OES detector 172 for making OES measurements. Injection of additional gases by the controller 170 into the exhaust line 136 near or at the location where the exhaust plasma chamber 123 is coupled to it may help in maintaining a more stable plasma source discharge. This may widen the operating window of the exhaust plasma chamber 123. Additionally, different types of gases can be selected by the controller 170 to alter plasma discharge parameters such as plasma temperature Tₑ and electron density Ne. This may provide more effective ionization of, for example, byproducts generated during an etch process in the processing chamber 110, which can increase endpoint detection (EPD) sensitivity for the etch process. As such, the controller 170 may be able to determine an endpoint event with increased sensitivity from the OES detector 172 and thereby stop an etch process. The additional gases can also be used for additional characterization and analysis of the etch byproducts and endpoint detection by the controller 170. In other words, by controlling the chemistry of the plasma inside the exhaust plasma chamber 123, the controller 170 may be able to use advanced OES metrology algorithms, such as a particular pressure or gas composition or scanning over these parameters for a selected semiconductor process recipe.

The configuration of the semiconductor processing system 10 described above with respect to FIG. 1 is included as an example of a processing system that may be used with an improved optical emission spectroscopy (OES) system. In alternative examples, various alternative configurations may be used for the semiconductor processing system to be used with the improved optical emission spectroscopy (OES) system. For example, the semiconductor processing system may be a resonator such as a helical resonator that produces helicons. Further, microwave plasma (MW), electron cyclotron resonance (ECR), multi-frequency CCP, or other suitable systems may be used. In various examples, the RF power, chamber pressure, substrate temperature, gas flow rates and other semiconductor process parameters may be selected in accordance with the respective process recipe. Other configurations of pumps for the exhaust line 136 that couples with the exhaust plasma chamber 123 may be used as well, and all such configurations are within the scope of the disclosed embodiments.

In addition, embodiments of the present disclosure may be also applied to remote plasma systems as well as batch systems. For example, the substrate holder may be able to support a plurality of remote sensors and/or semiconductor substrates (e.g., wafers) that are spun around a central axis as they pass through different plasma zones. Accordingly, it is possible to have multiple plasma zones, for example, including a metal-containing plasma zone, metal-free plasma zone, and plasma-free zone (e.g., a purge zone). Furthermore, embodiments of the present disclosure may be further applied to other processing systems including gas phase thermal plasma-less systems and/or systems employing weakly ionized gases.

FIG. 2 illustrates an example optical emission spectroscopy (OES) graph of an argon (Ar) 602 nm emission line. However, noise and/or oscillations (illustrated in FIG. 2 between 30 and 50 seconds) are present in the collected spectrum due to a discharge instability. Optical emission spectroscopy signal strength may depend on the number of excited species in a plasma (in other words, on the plasma density), which itself may depend on the amount of power coupled with the plasma. It is beneficial for the plasma discharge used to generate the photons to be very stable in order to make accurate measurements with OES (e.g., an accurate determination of an endpoint for an etch process), as noise or oscillations such as illustrated by FIG. 2 can disturb the measurements.

The operating window of OES plasma excitation units may be limited by pressure (such as an operational pressure Poperation in a range of 10 mT to 10 T) and gas species present in the system. These parameters may be dependent on the semiconductor process being performed in the processing chamber, the geometry of the exhaust line, and the pumping speed of the roughing pump (e.g., a turbomolecular pump). It may be challenging to control these parameters without changing the recipe of the semiconductor process. As such, the improved OES system with additional gas injection and pressure feedback control as described above with respect to FIG. 1 provides advantageous additional knobs for achieving desirable plasma stability. The improved OES system further provides control of the plasma chemistry in the OES exhaust plasma unit, which may be advantageous for performing advanced OES metrology.

FIG. 3 illustrates an OES spectrum graph, in accordance with some embodiments. OES spectra may be determined by electron temperature Tₑ and gas composition, and OES intensity from the plasma may be proportional to the electron density nₑ, which may be determined by the source power of the plasma and its composition. The sample OES spectrum illustrated by FIG. 3 demonstrates that substituting helium (He) for argon (Ar) as a carrier gas may increase the OES signal intensity acquired using the improved OES system described above with respect to FIG. 1. As such, changing the species of injected gas, such as the carrier gas, into the exhaust plasma chamber 123 (see above, FIG. 1) may provide a knob for additional OES characterization. This may be advantageous by enabling the use of actinometry by the improved OES system. Actinometry may use the emission of additional, non-reactive species that are present in trace amounts to correct emission intensity of target species for the rate of electron excitation. In other words, it may be advantageous to add one or more additional gases to the exhaust plasma chamber 123 in order to increase the sensitivity of the OES detector 172 to target species from a semiconductor process in the processing chamber 110. For example, adding helium as a carrier gas to the exhaust plasma chamber 123 may increase the overall intensity of the plasma discharge due to the increase in electron temperature of the plasma discharge and thereby lead to an increase of the OES endpoint detection sensitivity. For a target species such as nitrogen (e.g., from a nitride etch stop layer), He can be injected to the external plasma unit as a carrier gas in order to improve end point detection for an etch process.

FIGS. 4A-4D illustrate an example process for processing a substrate while using the improved OES system (see above, FIG. 1) to perform measurements, in accordance with some embodiments. FIGS. 4A-4C illustrate cross sectional views of a semiconductor structure 200 illustrating the formation of a high aspect ratio opening in a substrate 202, and FIG. 4D illustrates the formation of a conductive feature in the high aspect ratio opening. High aspect ratio openings (e.g., openings with aspect ratios greater than 10:1, such as greater than 20:1 or greater than 50:1) can be trenches or holes with rectangular, square, circular (as in contacts) or any other regular or irregular shapes.

In some embodiments, the substrate 202 comprises a semiconductor substrate 206 such as a semiconductor wafer with an overlying dielectric layer 208. In some embodiments, the semiconductor substrate 206 is a silicon wafer, or a silicon-on-insulator (SOI) wafer. In certain embodiments, the semiconductor substrate 206 comprises a silicon germanium wafer, silicon carbide wafer, gallium arsenide wafer, gallium nitride wafer and other compound semiconductors. In other embodiments, the semiconductor substrate 206 comprises heterogeneous layers such as silicon germanium on silicon, gallium nitride on silicon, silicon carbon on silicon, as well layers of silicon on a silicon or SOI substrate. In an embodiment, the semiconductor substrate 206 is a single crystal semiconductor substrate such as a single crystal silicon wafer or a silicon-on-insulator substrate.

In various embodiments, the semiconductor structure 200 is patterned or embedded in other components of a semiconductor device. In various embodiments, the substrate 202 may be a part of a semiconductor device, and may have undergone a number of steps of processing following, for example, a conventional process. The substrate 202 accordingly may comprise layers of semiconductors useful in various microelectronics. For example, the semiconductor structure 200 may comprise a dielectric layer 208 (also referred to as a back end of line (BEOL) layer) in which various device regions are formed. The dielectric layer 208 may comprise silicon oxide, silicon dioxide, the like, or a combination thereof.

A photomask layer 204 is deposited on the substrate 202. In some embodiments, the photomask layer 204 is a trilayer photomask with a bottom organic (ODL) layer, a middle antireflective coat layer, and a top photoresist layer. However, any suitable photomask may be used for the photomask layer 204.

In FIG. 4B, a first opening 210 is formed in the photomask layer 204 using conventional photolithography techniques. As an example, the photomask layer 204 is exposed to a light pattern, such as an ultraviolet (UV), a far ultraviolet (FUV), or an extreme ultraviolet (EUV) exposure. A photomask may be used to create a light pattern by placing the photomask between the substrate 202 and a light source (not illustrated). In response to the exposure to the light pattern, a photoreaction may occur in exposed regions of the photomask layer 204, while unexposed regions remain unchanged. As a result of the photoreaction, the exposed regions may comprise a cross-linked photoresist film, which may have material properties substantially different from the unreacted portion of the photomask layer 204. Such a difference in the material properties includes volatility, reactivity, and/or solubility among others, which gives origin to the tonality as a photoresist.

Next, after exposure to the light pattern, a development process is performed on the substrate 202 with a reactive precursor. In some embodiments, the development process is a plasma-less process performed with a gaseous (non-ionized) reactive precursor (also referred to as a developing gas). The reactive precursor reacts with, e.g., the unexposed regions of the photomask layer 204 to produce volatile by-products, which then evaporate from the surface of the substrate 202 to form a first opening 210. This reaction develops the photomask layer 204. In some embodiments, the reactive precursor is a reactive gas such as hydrogen bromide (HBr), hydrogen chloride (HCl), boron trichloride (BCl₃), organic acids such carboxylic acids, methanol, ethanol, isopropyl alcohol, the like, or a mixture or combination thereof.

Next, in FIG. 4C, the first opening 210 is etched through the dielectric layer 208 with a plasma process 220 to form a high aspect ratio (HAR) second opening 222, in accordance with some embodiments. The plasma process 220 may be performed in an example semiconductor processing system 10 as described above with respect to FIG. 1. For example, the semiconductor structure 200 may be provided into the example semiconductor processing system 10 and being placed on the substrate holder 105 (such as in the place of the substrate 100; see above, FIG. 1).

In some embodiments, the plasma process 220 etches the high aspect ratio second opening 222 into the semiconductor substrate 206, such as to a depth in a range of 10 μm to 100 μm. In other embodiments, the high aspect ratio second opening 222 stops on the semiconductor substrate 206. The high aspect ratio second opening 222 can be rectangular, square, circular (as in contacts) or any other regular or irregular shape and may be formed like a trench or hole in various embodiments.

Byproducts of the plasma process 220 (e.g., species removed by an etch process) may be removed from the processing chamber 110 by the turbomolecular pump 135 and passed through the exhaust line 136 to the exhaust plasma chamber 123. As described above with respect to FIG. 1, the controller 170 may receive OES measurements of a plasma generated in the exhaust plasma chamber 123 from the OES detector 172 while controlling pressure and plasma chemistry in the exhaust plasma chamber 123 with feedback from the pressure gauge 124 and the flow controller 127 (see above, FIG. 1). This may be advantageous for improved OES characterization of the plasma process 220, such as for endpoint detection of the plasma process 220. In various embodiments, the controller 170 is configured to end the plasma process 220 when the OES detector 172 detects a desired signal (for example, emissions related to species of interest appearing as changes in the intensity of end point related emission lines) in the exhaust from the plasma process 220. In some embodiments, the controller 170 is configured to end a plasma-less process (e.g., the development process described above with respect to FIG. 4B) when an endpoint related signal of the plasma-less process (e.g., changes in the entire OES intensity due to changes in the exhaust gas composition from depletion of plasma-less process byproducts) is detected with the OES detector 172.

In FIG. 4D, a conductive feature 250 is formed in the high aspect ratio (HAR) second opening 222 (see above, FIG. 4C). In various embodiments, the conductive feature 250 is a high aspect ratio feature (e.g., a through substrate via (TSV)). The conductive feature 250 may be formed to physically and electrically couple with conductive portions of the substrate 202, such as conductive features in the dielectric layer 208. As an example of forming the conductive feature 250, a conformal barrier metal (e.g., TiN or TaN) liner is formed over the exposed surfaces of the dielectric layer 208 and the semiconductor substrate 206. Next, the high aspect ratio second opening 222 is filled with a conductive material such as a metal. For example, the conductive material may be copper formed using electroplating. However, any suitable conductive material and deposition method may be used. Excess conductive material is then removed from the top surface of the dielectric layer 208 using a planarization process (e.g., a CMP), thereby forming the conductive feature 250 inlaid in the substrate 202.

In some embodiments, after forming the conductive feature 250, a bottom surface of the semiconductor substrate 206 is recessed to expose a respective bottom surface of the conductive feature 250. For example, the semiconductor structure 200 may be flipped over and placed on a carrier. The semiconductor substrate 206 is then recessed to expose the conductive feature 250 with a suitable process, such as a wafer backgrinding. However, any suitable method may be used to expose a respective bottom surface of the conductive feature 250.

Although FIGS. 4A-4D illustrate the formation of a single high aspect ratio second opening 222 with a plasma process 220 and a single conductive feature 250 being formed in the high aspect ratio second opening 222, it should be understood that this is disclosed as a non-limiting example. Any suitable number of high aspect ratio second openings 222 may be formed with one or more plasma processes 220, one or more plasma-less processes, the like, or a combination thereof, and be filled with respective conductive features 250. Additionally, the process described above with respect to FIGS. 4A-4D is included as an example, and the improved OES system may be used to perform measurements for endpoint detection for other etch processes or metrology for any suitable semiconductor process, and all such methods are within the scope of the disclosed embodiments.

FIG. 5 illustrates a process flow chart diagram of a method 300 for a semiconductor process, in accordance with some embodiments. In step 310, a semiconductor process is performed in a semiconductor processing chamber, as described above with respect to FIGS. 1 and 4C. In step 320, an exhaust from the semiconductor process is pumped into an exhaust plasma chamber coupled with the semiconductor process chamber, as described above with respect to FIG. 1. In step 330, a plasma is generated in the exhaust plasma chamber from the exhaust, as described above with respect to FIG. 1.

In step 340, a pressure is adjusted inside the exhaust plasma chamber by injecting a gas based on pressure readings from a pressure gauge coupled with the exhaust plasma chamber, as described above with respect to FIG. 1. In step 350, an optical emission spectroscopy (OES) measurement is performed on the plasma, as described above with respect to FIG. 1.

Example embodiments of the disclosure are summarized here. Other embodiments can also be understood from the entirety of the specification as well as the claims filed herein.
Example 1. A system for gas measurement, the system including: an exhaust line coupled with a semiconductor processing chamber; an exhaust plasma chamber coupled with the exhaust line, the exhaust plasma chamber configured to generate a plasma from gas received through the exhaust line; an optical emission spectroscopy (OES) detector coupled to the exhaust plasma chamber; and a flow controller device coupled to the exhaust plasma chamber and the exhaust line by a gas injection line, the flow controller device configured to inject gas into the exhaust plasma chamber.
Example 2. The system of example 1, further including a pressure gauge coupled with the exhaust plasma chamber.
Example 3. The system of one of examples 1 or 2, further including a turbomolecular pump coupled between the semiconductor processing chamber and the exhaust line.
Example 4. The system of one of examples 1 to 3, where the flow controller device is further coupled to a gas supply, the gas supply being configured to provide one or more gases from the group of argon (Ar), helium (He), xenon (Xe), nitrogen (N₂), and oxygen (O₂).
Example 5. The system of one of examples 1 to 4, further including a controller coupled with the OES detector and the flow controller device, the controller being configured to control a pressure inside the exhaust plasma chamber.
Example 6. The system of example 5, where the controller is further configured to add a gas to the exhaust plasma chamber, the gas increasing the sensitivity of the OES detector to a target species.
Example 7. A system for semiconductor processing, the system including: a semiconductor processing chamber; a turbomolecular pump coupled to the semiconductor processing chamber, the turbomolecular pump configured to remove exhaust gas from the semiconductor processing chamber; an exhaust plasma chamber coupled with the turbomolecular pump, the exhaust plasma chamber including a viewport, the exhaust plasma chamber configured to generate a plasma from the exhaust; an optical emission spectroscopy (OES) detector coupled to the viewport by a fiber optic cable; a flow controller device coupled with the exhaust plasma chamber by a gas injection line, the flow controller device configured to inject gas into the exhaust plasma chamber; a pressure gauge coupled with the exhaust plasma chamber; and a controller coupled with the OES detector, the flow controller device, and the pressure gauge, the controller being configured to: receive pressure feedback data from the pressure gauge; receive data from the OES detector; and control a pressure in the exhaust plasma chamber by sending control signals to the flow controller device.
Example 8. The system of example 7, further including an automatic pressure control valve between the semiconductor processing chamber and the turbomolecular pump.
Example 9. The system of one of examples 7 or 8, where the flow controller device is configured to inject a carrier gas.
Example 10. The system of one of examples 7 or 8, where the flow controller device is configured to inject a volatile gas.
Example 11. The system of one of examples 7 to 10, further including an exhaust line between the turbomolecular pump and a dry pump, the exhaust plasma chamber being coupled with the exhaust line.
Example 12. The system of one of examples 7 to 11, where the controller is further configured to select a gas for injection into the exhaust plasma chamber, the gas altering discharge parameters of the plasma.
Example 13. The system of one of examples 7 to 12, where controlling the pressure in the exhaust plasma chamber maintains a stable plasma source discharge in the exhaust plasma chamber.
Example 14. A method for semiconductor processing, the method including: performing a semiconductor process in a semiconductor processing chamber; pumping an exhaust from the semiconductor process into an exhaust plasma chamber coupled with the semiconductor processing chamber; generating a plasma in the exhaust plasma chamber from the exhaust; based on pressure readings from a pressure gauge coupled with the exhaust plasma chamber, adjusting a pressure inside the exhaust plasma chamber by injecting a gas; and performing an optical emission spectroscopy measurement on the plasma.
Example 15. The method of example 14, where injecting the gas increases a sensitivity of the optical emission spectroscopy measurement to a target species.
Example 16. The method of one of examples 14 or 15, where the semiconductor process is an etch process.
Example 17. The method of example 16, where the optical emission spectroscopy measurement is an endpoint detection for the etch process.
Example 18. The method of one of examples 14 to 17, where adjusting the pressure inside the exhaust plasma chamber stabilizes the plasma in the exhaust plasma chamber.
Example 19. The method of one of examples 14 to 18, where injecting the gas includes injecting argon (Ar), helium (He), or xenon (Xe).
Example 20. The method of one of examples 14 to 19, where injecting the gas includes injecting nitrogen (N₂) or oxygen (O₂).

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A system for gas measurement, the system comprising:
an exhaust line coupled with a semiconductor processing chamber;
an exhaust plasma chamber coupled with the exhaust line, the exhaust plasma chamber configured to generate a plasma from gas received through the exhaust line;
an optical emission spectroscopy (OES) detector coupled to the exhaust plasma chamber; and
a flow controller device coupled to the exhaust plasma chamber and the exhaust line by a gas injection line, the flow controller device configured to inject gas into the exhaust plasma chamber.

2. The system of claim 1, further comprising a pressure gauge coupled with the exhaust plasma chamber.

3. The system of claim 1, further comprising a turbomolecular pump coupled between the semiconductor processing chamber and the exhaust line.

4. The system of claim 1, wherein the flow controller device is further coupled to a gas supply, the gas supply being configured to provide one or more gases from the group of argon (Ar), helium (He), xenon (Xe), nitrogen (N₂), and oxygen (O₂).

5. The system of claim 1, further comprising a controller coupled with the OES detector and the flow controller device, the controller being configured to control a pressure inside the exhaust plasma chamber.

6. The system of claim 5, wherein the controller is further configured to add a gas to the exhaust plasma chamber, the gas increasing the sensitivity of the OES detector to a target species.

7. A system for semiconductor processing, the system comprising:
a semiconductor processing chamber;
a turbomolecular pump coupled to the semiconductor processing chamber, the turbomolecular pump configured to remove exhaust gas from the semiconductor processing chamber;
an exhaust plasma chamber coupled with the turbomolecular pump, the exhaust plasma chamber comprising a viewport, the exhaust plasma chamber configured to generate a plasma from the exhaust;
an optical emission spectroscopy (OES) detector coupled to the viewport by a fiber optic cable;
a flow controller device coupled with the exhaust plasma chamber by a gas injection line, the flow controller device configured to inject gas into the exhaust plasma chamber;
a pressure gauge coupled with the exhaust plasma chamber; and
a controller coupled with the OES detector, the flow controller device, and the pressure gauge, the controller being configured to:
receive pressure feedback data from the pressure gauge;
receive data from the OES detector; and
control a pressure in the exhaust plasma chamber by sending control signals to the flow controller device.

8. The system of claim 7, further comprising an automatic pressure control valve between the semiconductor processing chamber and the turbomolecular pump.

9. The system of claim 7, wherein the flow controller device is configured to inject a carrier gas.

10. The system of claim 7, wherein the flow controller device is configured to inject a volatile gas.

11. The system of claim 7, further comprising an exhaust line between the turbomolecular pump and a dry pump, the exhaust plasma chamber being coupled with the exhaust line.

12. The system of claim 7, wherein the controller is further configured to select a gas for injection into the exhaust plasma chamber, the gas altering discharge parameters of the plasma.

13. The system of claim 7, wherein controlling the pressure in the exhaust plasma chamber maintains a stable plasma source discharge in the exhaust plasma chamber.

14. A method for semiconductor processing, the method comprising:
performing a semiconductor process in a semiconductor processing chamber;
pumping an exhaust from the semiconductor process into an exhaust plasma chamber coupled with the semiconductor processing chamber;
generating a plasma in the exhaust plasma chamber from the exhaust;
based on pressure readings from a pressure gauge coupled with the exhaust plasma chamber, adjusting a pressure inside the exhaust plasma chamber by injecting a gas; and
performing an optical emission spectroscopy measurement on the plasma.

15. The method of claim 14, wherein injecting the gas increases a sensitivity of the optical emission spectroscopy measurement to a target species.

16. The method of claim 14, wherein the semiconductor process is an etch process.

17. The method of claim 16, wherein the optical emission spectroscopy measurement is an endpoint detection for the etch process.

18. The method of claim 14, wherein adjusting the pressure inside the exhaust plasma chamber stabilizes the plasma in the exhaust plasma chamber.

19. The method of claim 14, wherein injecting the gas comprises injecting argon (Ar), helium (He), or xenon (Xe).

20. The method of claim 14, wherein injecting the gas comprises injecting nitrogen (N₂) or oxygen (O₂).
